(19) United States
(12) Patent Application Publication
(10) Pub. No.: US 2016/0137502 A1
(43) Pub. Date: May 19, 2016

(54) BORON NITRIDE NANOSHEETS AND METHODS OF MAKING AND USING THE SAME

(71) Applicant: MICHIGAN TECHNOLOGICAL UNIVERSITY, Houghton, MI (US)

(72) Inventors: Sawyer Hopkins, Manhattan, KS (US); Dongyan Zhang, Houghton, MI (US); Boyi Hao, Houghton, MI (US); Anjana Asthana, Houghton, MI (US); Yoke Khin Yap, Houghton, MI (US)

(21) Appl. No.: 14/944,136

(22) Filed: Nov. 17, 2015

Related U.S. Application Data
(60) Provisional application No. 62/080,453, filed on Nov. 17, 2014.

(51) Int. Cl. C01B 21/064; C23C 16/56; C23C 16/01; C09K 5/14; C23C 16/34

(52) U.S. Cl. CPC C01B 21/0641; C09K 5/14; C23C 16/342; C23C 16/01; C23C 16/56; C01P 2006/32; C01P 2004/24; Y10S 977/755; Y10S 977/891; B82Y 40/00

(57) ABSTRACT

This disclosure provides boron nitride nanosheets, and methods of making and using the same. The boron nitride nanosheets may be made by heating solid boron, magnesium oxide and iron oxide compounds in a furnace in the presence of ammonia gas and a substrate, such that the boron nitride nanosheet is deposited on the substrate, where the boron nitride nanosheet comprises a first end, a second end, and a sheet between the first and second ends, where the first end is engaged with the substrate and the sheet extends upward away from the substrate and then curls back towards the substrate so that the second end is oriented towards the substrate.

### CROSS-REFERENCE TO RELATED APPLICATIONS

This application claims priority to U.S. Provisional Application No. 62/080,453, filed Nov. 17, 2014, the complete disclosure of which is hereby incorporated by reference.

### STATEMENT REGARDING FEDERALLY FUNDED RESEARCH

This invention was made with U.S. Government support under CAREER Award 0447555 and Award 1261910 from the National Science Foundation, and Grant No. DE-FG02-06ER46294 from the Department of Energy. The U.S. Government has certain rights in the invention.

### FIELD OF INVENTION

This disclosure relates to nanosheets made of boron nitride which display certain physical properties, their synthesis and applications thereof. Specifically, this disclosure relates to making nanoscale materials, their peeling and transfer processes, and their application in cooling hot surfaces including those in electronic and electrical devices, and power plants. The disclosure further relates to thin sheets of boron nitride which have wavy edges that are scrolled, forming three-dimensional (3D) structures. The invention further relates to contact between the materials and surfaces that reduce the heat transfer resistance between the surfaces and the materials.

### BACKGROUND

Thermal management of items is becoming increasingly becoming more important, particularly in electronic and opto-electronic devices, because insufficient or ineffective thermal management may negatively impact the performance and long-term reliability of such devices. New thermal management materials are continuously being developed. Boron nitride materials (such as boron nitride nanosheets (BNNSs) and boron nitride nanotubes (BNNTs) have been identified as potentially being effective for thermal management. However, existing methods for making boron nitride structures are very expensive and/or require the use of toxic processes. Moreover, the method by which a boron nitride nanostructure is made affects both its three-dimensional structure and function.

### SUMMARY

This disclosure provides methods of making boron nitride nanosheets (BNNSs), which include heating solid boron, magnesium oxide and iron oxide compounds in a furnace in the presence of ammonia gas and a substrate, such that a boron nitride nanosheet is deposited on the substrate, wherein the boron nitride nanosheet comprises a first end, a second end, and a sheet between the first and second ends, wherein the first end is engaged with the substrate and the sheet extends upward away from the substrate and then curls back towards the substrate so that the second end is oriented towards the substrate. This disclosure also provides boron nitride nanosheets formed according to these methods, and compositions comprising a substrate having a surface at least partially coated with a coating comprising a plurality of boron nitride nanosheets made according to these methods. This disclosure also provides methods of using these boron nitride nanosheets to dissipate heat from a surface.

This disclosure also provides compositions comprising a substrate and a boron nitride nanosheet comprising a first end, a second end, and a sheet between the first and second ends, wherein the first end is engaged with the substrate and the sheet extends upward away from the substrate and then curls back towards the substrate so that the second end is oriented towards the substrate.

This disclosure also provides compositions comprising a surface and a coating at least partially coating the surface, where the coating comprises a first layer in direct contact with the surface that includes a plurality of boron nitride nanosheets, and a second layer in contact with the first layer that includes a plurality of boron nitride nanotubes

Other aspects of the invention will become apparent by consideration of the detailed description and accompanying drawings.

### BRIEF DESCRIPTION OF THE DRAWINGS

This patent or application file contains at least one drawing executed in color. Copies of this patent or patent application publication with color drawing(s) will be provided by the Office upon request and payment of the necessary fee.

FIG. 1A is a scanning electron microscopy (SEM) image of BNNSs made according to the methods disclosed herein.

FIG. 1B is a schematic of showing an exemplary substrate having a surface at least partially with a coating comprising a plurality of BNNSs.

FIG. 1C is a schematic showing a side view of BNNSs deposited on a substrate according to existing methods.

FIG. 1D is a schematic showing a side view of BNNSs deposited on a substrate according to the methods of the present disclosure.

FIG. 2A-FIG. 2D are high-magnification transmission electron microscopy (TEM) images of exemplary BNNSs made according to the methods of the present disclosure, which show that the BNNSs have scrolled and closed ends.

FIG. 3 is a schematic layout of a chemical vapor deposition (CVD) chamber used for making the BNNSs of the present disclosure.

FIG. 4A-FIG. 4F show SEM images of various samples of BNNSs synthesized using a CVD chamber according to FIG. 3.

FIG. 5A and FIG. 5B. FIG. 5A is a graph comparing the rate of cooling between 130° C. and 40° C. for three samples: a Si substrate alone (Si); a silica substrate coated with a coating comprising BNNSs (BNNS); and a silica substrate coated with a coating comprising BNNTs (BNNT). FIG. 5A also includes a schematic (inset) showing the process used to heat the samples. FIG. 5B is a graph showing a magnified view of the cooling curves from FIG. 5A over the 0-600 second time period, along with a linear fit to the data in this time period.

FIG. 6A-FIG. 6C is a series of SEM images showing the surface morphologies of FIG. 6A a bare Si substrate, FIG. 6B sample BNNSs-1, and FIG. 6C sample BNNSs-2.

FIG. 7A-FIG. 7C. FIG. 7A is a graph showing the cooling profiles of exemplary samples BNNSs-1 and BNNSs-2 compared to bare Si. FIG. 7B is a photograph of water droplets on (from left to right) BNNSs-2, BNNSs-1, and bare Si. FIG. 7C is a photograph of a water droplet wetting BNNSs-2.

FIG. 8 is a schematic drawing showing a contact angle between a surface and a drop of water.

FIG. 9A-FIG. 9C are photographs showing the peeling of an exemplary PMMA/BNNS film after removing the film from a substrate.

FIG. 9D-FIG. 9F. FIG. 9D is an SEM image of the BNNSs as formed on the substrate. FIG. 9E is an SEM image of the substrate after removal of the PMMA/BNNS film, showing that the BNNSs are fully transferred to the PMMA/BNNS film. FIG. 9F is an SEM image of the surface of a secondary substrate after the PMMA/BNNS film was used to transfer the BNNSs to the surface.

FIG. 10 is a pair of SEM images showing the morphology of compositions comprising BNNSs applied to a Si substrate before being overgrown with BNNTs on top of the BNNSs (left) and after being overgrown with BNNTs on top of BNNSs (right).

FIG. 11 is a graph showing cooling curves of various samples including samples having BNNSs deposited onto Si substrates and a Si substrate alone.

FIG. 12 is a graph showing cooling curves of various samples including samples having BNNTs-BNNSs deposited onto Si substrates and a Si substrate alone.

FIG. 13 is a graph showing cooling curves of various samples having BNNSs deposited onto Si substrates.

FIG. 14 is a graph showing cooling curves of various samples having BNNTs-BNNSs deposited onto Si substrates.

### DETAILED DESCRIPTION

Before any embodiments of the invention are explained in detail, it is to be understood that the invention is not limited in its application to the details of construction and the arrangement of components set forth in the following description or illustrated in the drawings. The invention is capable of other embodiments and of being practiced or of being carried out in various ways.

The present disclosure provides methods for making a structurally unique class of boron nitride nanosheets (BNNSs) having different structure and function than those prepared by known methods. Rather than having the open-ended morphologies of the BNNSs prepared according to known methods, the BNNSs of the present disclosure are scrolled backwards so as to form a close-ended structure at the position furthest from the substrate. As will be discussed in more detail below, these BNNSs provide good contact with a hot surface and are not water repelling. These BNNSs thus allow for contact with water-based or other coolants, or cooling air or other gases, to promote heat dissipation. The inventive BNNSs have feature sizes ranging from about 100 to about 500 nm, and transmission electron microscopy (TEM) images of these BNNSs show that the edges are scrolled and close-ended.

Boron nitride (BN) phases are structurally similar to those of carbon solids, and exist as, for example, hexagonal phase-BN (h-BN), cubic phase-BN (c-BN), BN nanotubes (BNNTs), BN nanosheets (BNNSs, single and few layered h-BN sheets), and BN nanoribbons (BNNRs). These BN structures are analogous to graphite, diamonds, carbon nanotubes (CNTs), graphene, and graphene nanoribbons (GNRs), respectively (Lee et at 2009, Yap 2011). Despite the structural similarity, the properties of BN materials are different from those of carbon solids. For example, graphite is electrically conducting, while h-BN is insulating. A property of the BN materials is their high heat conductivity, which may be applicable for advanced heat management.

In addition to their heat conductivity, there are structural properties that may affect the use of BN materials as thermal interface materials (TIMs), including the contact area with the hot surface, and the contact area with the cooling heat sink (solids) or coolant (air, gas, liquids, etc.). Larger contact areas between the TIMs and both the hot and cool regions can maximize the cooling rate. The electrical properties of TIMs will also impact their applications. For example, BN materials are electrically insulating and enable the dissipation of heat from electrical components without the risk of an electrical short circuit.

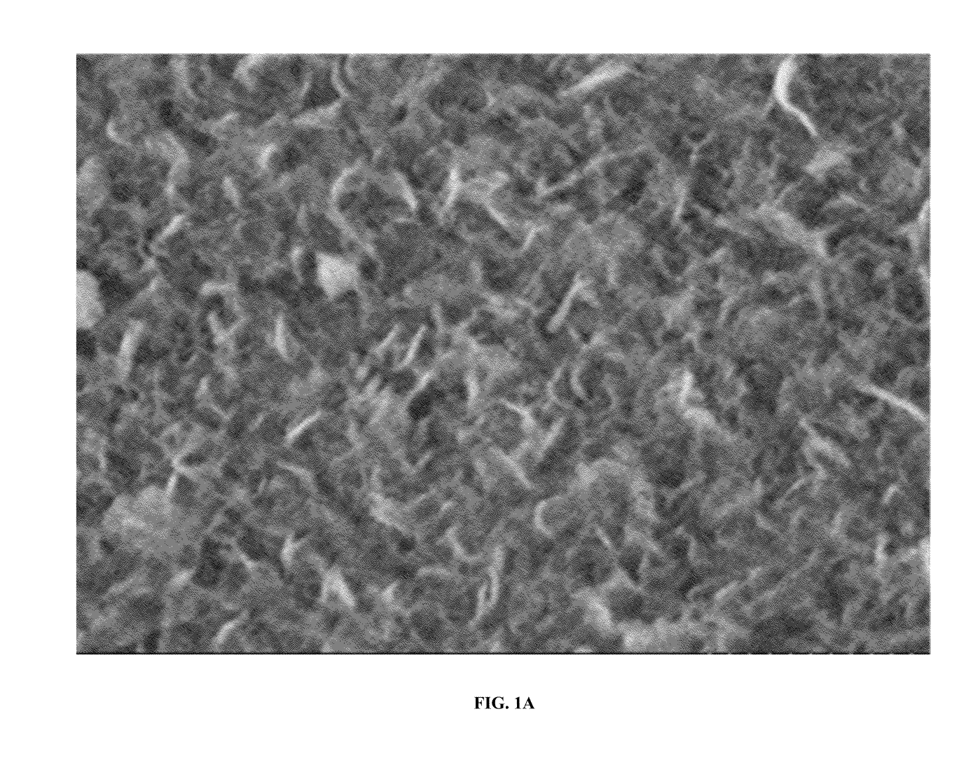

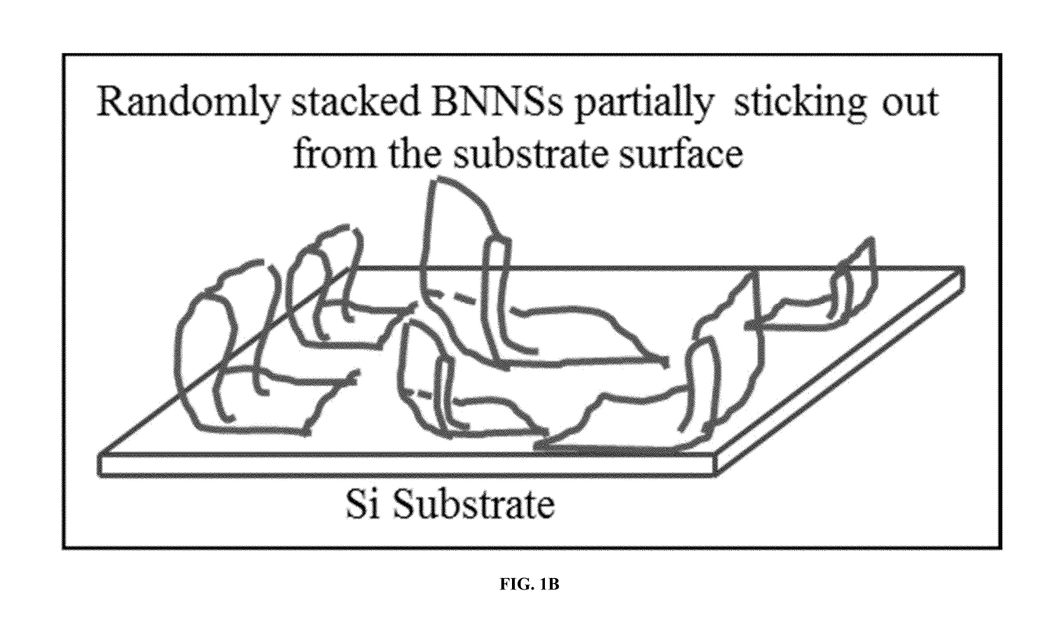

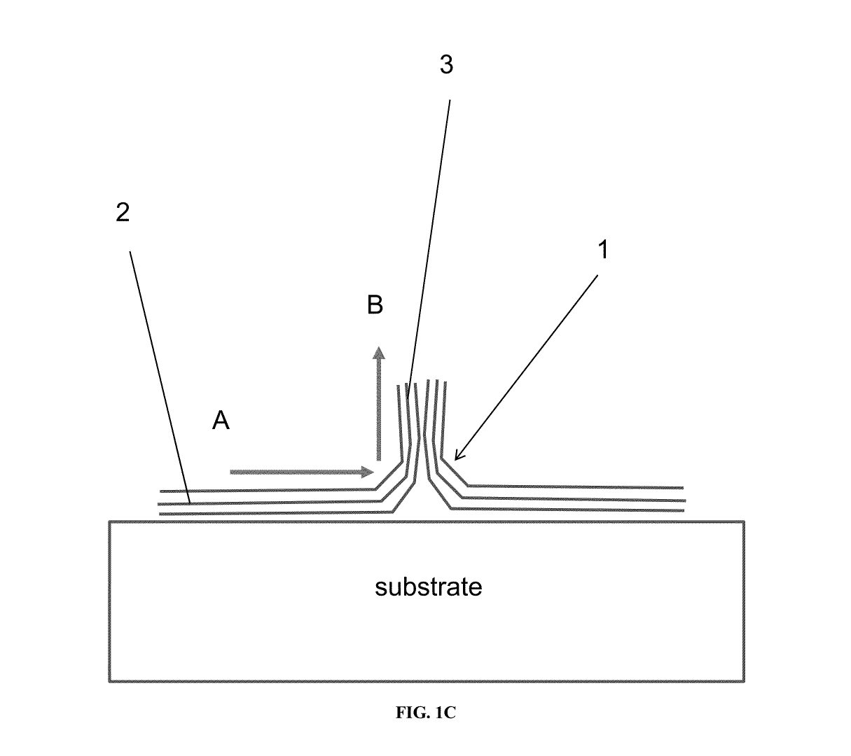

BNNSs are flat 2D materials when coated on hot surfaces or substrates. Flat BNNSs can contact the substrate or hot surface but are unable to offer additional contact area with surrounding coolants. Vertically aligned BNNSs (VA-BNNSs) have been described which are reported to be superhydrophobic (water repelling) but these have sharp open edges which project perpendicularly from the substrate surface, which may affect their water repelling properties and structural integrity. These VA-BNNSs are schematically shown in FIG. 1C and are discussed in more detail below.

In contrast, the BNNSs of the present disclosure have wavy edges that are scrolled so as to form closed end at the position furthest from the substrate. FIG. 1A is an SEM image of BNNSs made according to the methods of the present disclosure, which shows the wavy edges of the BNNSs. FIG. 1B schematically showing a Si substrate having a surface at least partially coated with a coating comprising a plurality of BNNSs that are scrolled to have closed ends.

FIG. 1C and FIG. 1D more specifically show the differences in morphology between the open-ended BNNSs formed according to known methods (FIG. 1C) and those formed according to the methods of the present disclosure (FIG. 1D). As can be seen in FIG. 1C, the open-ended BNNSs 1 formed according to known methods have a first end 2 and a second end 3, where the first end is engaged with the substrate (e.g., along direction A), and where the sheet curves and extends upward away from the substrate (e.g., along direction B) to the second end, which is oriented away from the substrate.

In contrast, as shown in FIG. 1D, the BNNSs 4 deposited on a substrate according to the methods of the present disclosure have a first end 5 and a second end 6, where the first end is engaged with the substrate (e.g., along direction A), and where the sheet curves and extends upward away from the substrate (e.g., along direction B), after which the sheet curls back towards the substrate (e.g. along direction C) so that the second end of the sheet is oriented towards the substrate. BNNSs deposited according to the methods of the present disclosure are thus scrolled backwards, and are close-ended at the position furthest from the substrate.

The BNNSs of the present disclosure allow for good contact with hot surfaces, and are not water repelling. As described below, the BNNSs of the present disclosure provide good contact between the surface or substrate and water-based or other coolants, and/or cooling air or gas, to promote heat dissipation.

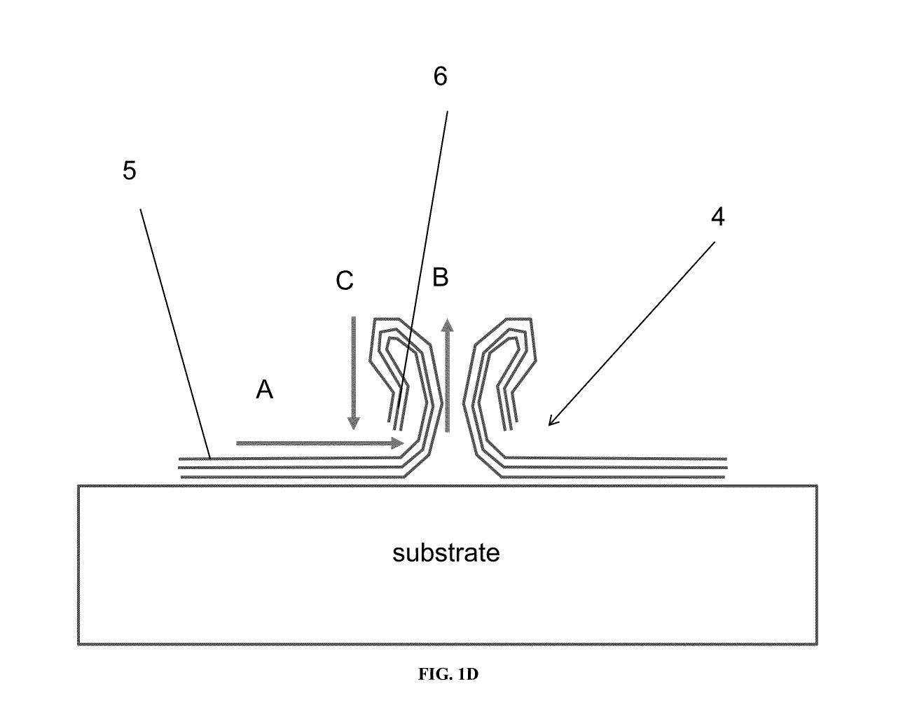

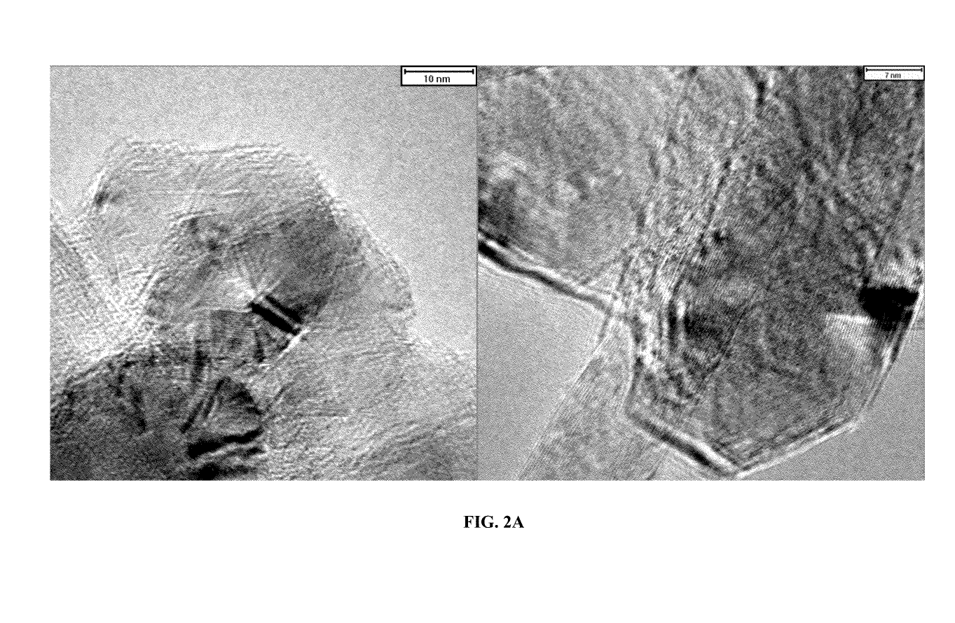

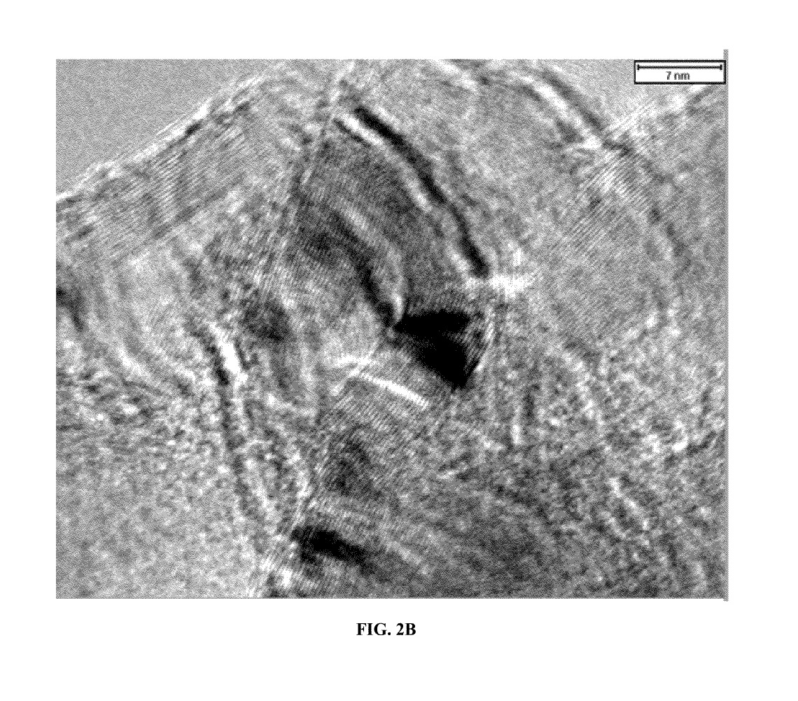

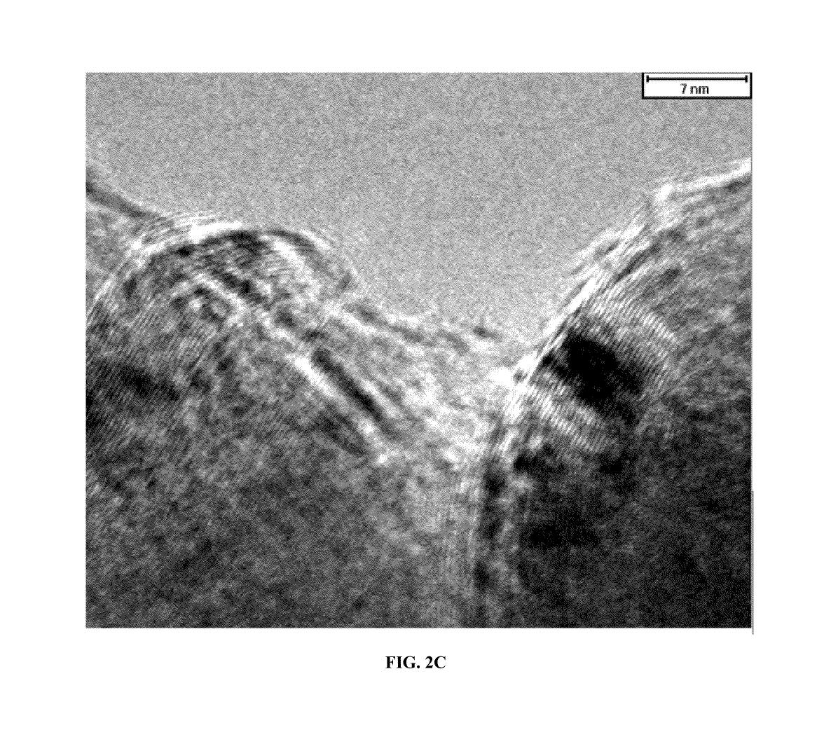

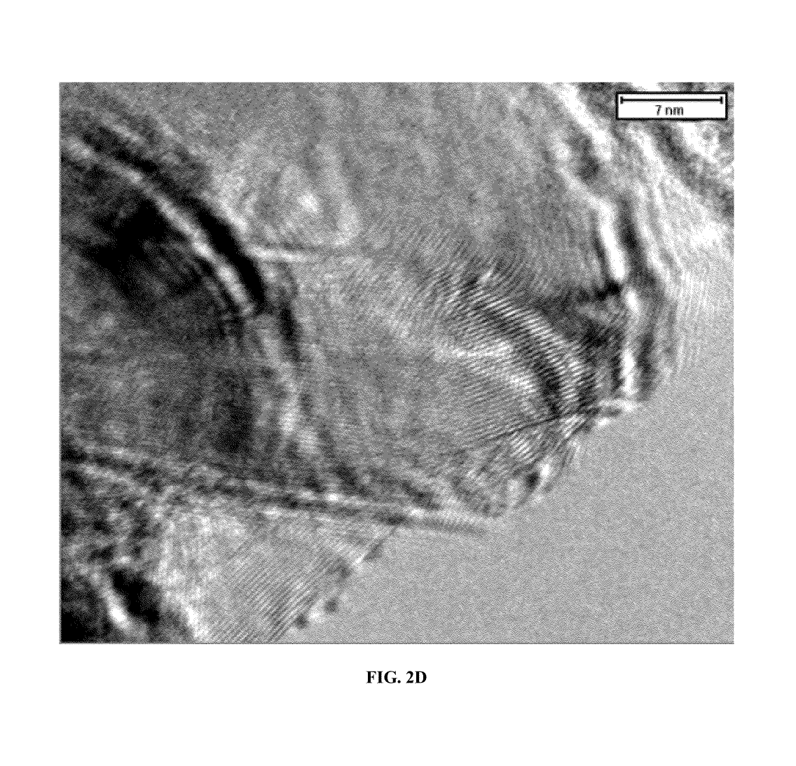

The BNNSs of the present disclosure have features ranging from about 100 to about 500 nm. TEM images show that the edges of these wavy BNNSs are scrolled and close-ended (FIGS. 2A-2D) and do not contain flat or straight h-BN layers.

The Synthesis of Wavy BNNSs.

The inventive wavy BNNSs can be synthesized by chemical vapor deposition (CVD) in a quartz tube chamber placed inside a standard resistive heating tube furnace. In an embodiment, about 0.3 g of mixed solid powder is placed in a combustion boat. In certain embodiments, up to about 1 gm of solids may be used. This powder consists of boron (B), magnesium oxide (MgO), and iron oxide in a molar ratio of about 4:1:1. A ratio of 2:1:1 was found to be unsatisfactory for efficient formation of the wavy BNNSs. The iron oxide may be FeO or Fe₂O₃, or mixtures thereof. The location of this combustion boat is at the approximate center of the furnace, in which the temperature is set at between about 1100° C. and about 1300° C. In some embodiments, the temperature is between about 1200° C. and about 1250° C., or about 1250° C. for Si substrates. In general, the temperature should not be so high as to possibly melt the substrate, and therefore the furnace temperature that is used is related to the type of substrate used.

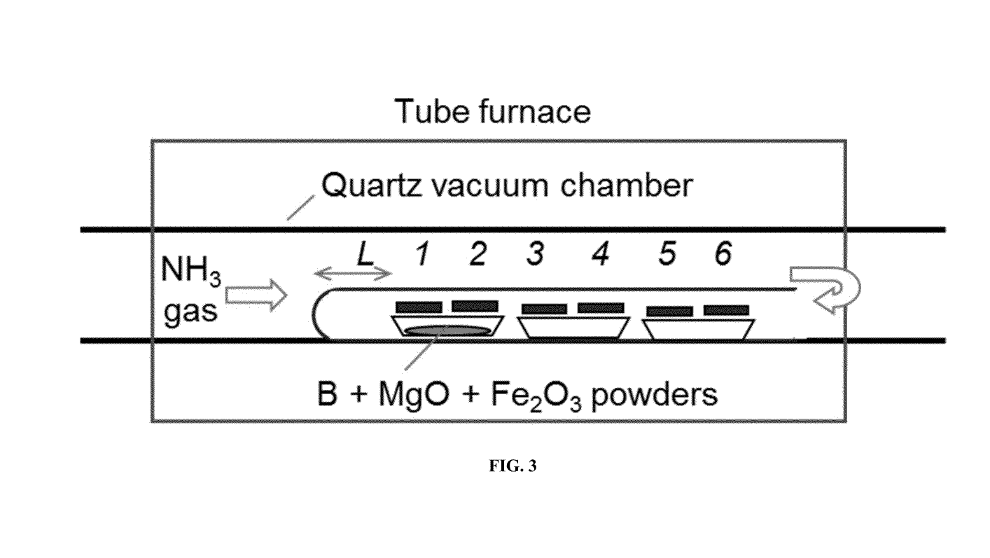

A series of combustion boats can be placed as shown in FIG. 3 without containing any powders. These boats may act as supports for additional substrates, in embodiments where multiple substrates are used. Without being bound by theory, it is believed that the BNNSs will not grow as efficiently if a substrate is farther from the middle of the furnace, as temperatures farther away (such as over about 4 inches away) from the center of the furnace may be cooler than temperatures in the center. In certain embodiments, a series of, or multiple, substrates may be used, and are placed on top of the boats. Any substrate that does not melt at the temperature of the furnace or that does not react with boron nitride may be used. Exemplary substrates include silicon (Si), oxidized silicon (e.g. SiO₂), sapphire, or quartz. The boats may be loaded into a close-ended quartz tube as shown in FIG. 3, with L ranging from about 3 to about 10 inches. BNNSs grow most efficiently when the distance L (where L is the length of the gap between the closed end of the quartz tube and the first combustion boat) is greater than about 3 inches. In an embodiment, the distance L is about 9 inches. The distance L is related to the amount of powder and temperatures used.

At the temperature of the furnace, the powders form boron oxide vapors which then react with ammonia gas (NH₃) and form BNNSs on the substrate. Any source of gaseous nitrogen may be used provided it decomposes at the operating temperature of the furnace. The pressure of the ammonia gas for efficient BNNS formation is between about 10 torr and about 100 torr, or at least about 3 torr. In certain embodiments, the pressure is between about 12 torr and about 15 torr, or about 12 torr. The NH₃ pressure of the chamber may be moderated by varying the gas flow rate and the evacuation rate. An exemplary flow rate of NH₃ of about 250 sccm allows the BNNSs to grow efficiently. The gas is preferentially flow in the direction shown in FIG. 3. The reaction proceeds between about 30 and about 60 minutes. In an embodiment, the reaction proceeds for at least about 30 minutes.

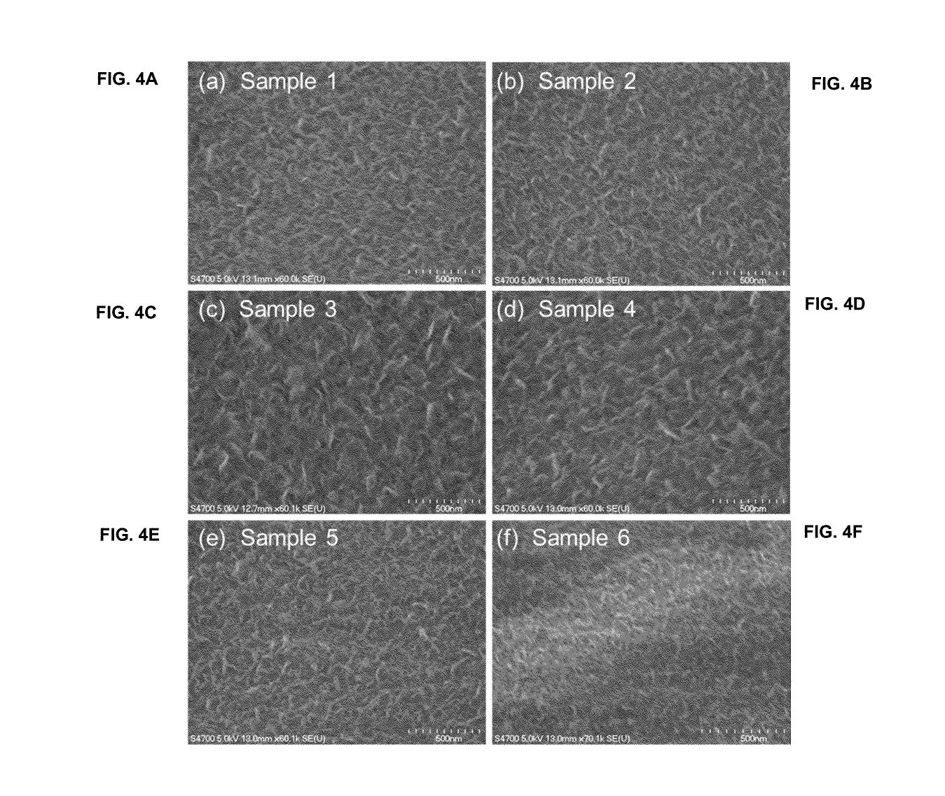

Wavy BNNSs as grown on the silicon substrates numbered 1 to 6 from FIG. 3 are shown in FIG. 4A-FIG. 4F; the different-numbered substrates are each in different positions within the furnace and thus each experiences slightly different conditions from the others such as differences in temperature. As can be seen, the feature sizes are smaller than about 300 nm for all the samples. These feature sizes are even smaller for Samples 5 and 6 (the image for sample 6 is shown at slightly larger magnification for clarity), which indicates that the feature size of the inventive BNNSs is controllable.

The Application of BNNSs for Heat Management.

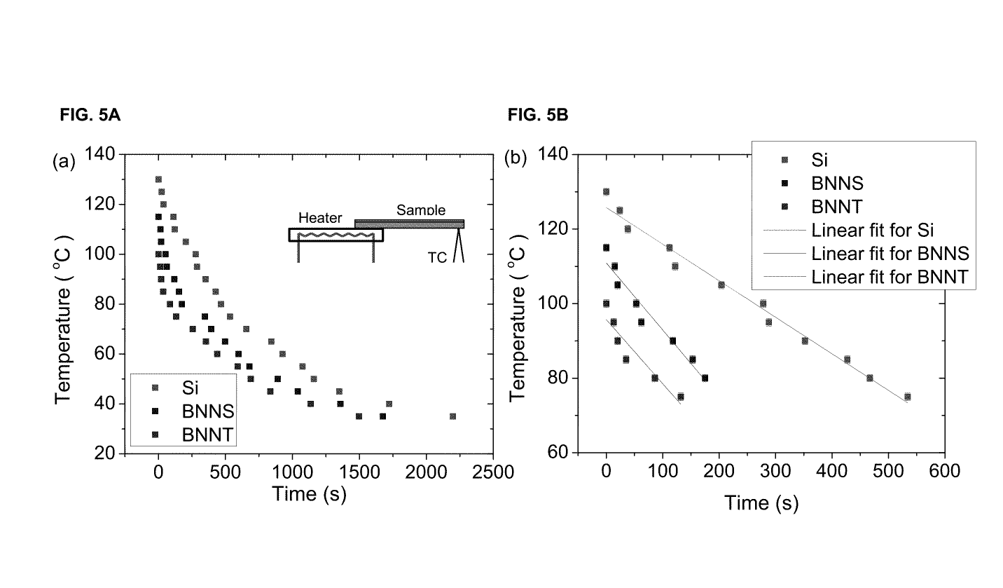

Various BNNTs and BNNSs were tested for their effects on dissipation of heat from the substrate. The sample preparation procedure of BNNTs was described elsewhere (Lee et al, 2008, and Lee et al, 2010). As shown in FIG. 5A, the cooling curves for a non-coated Si substrate, a BNNT coated Si substrate and a BNNS coated Si substrate are different, especially in the high temperature range. By linear fitting of the data in the first 600 seconds (FIG. 5B), the cooling gradients are determined to be −0.09812° C./s, −0.17217° C./s, and −0.17983° C./s for the Si, BNNT coated Si, and BNNS coated Si samples, respectively. This means that the BNNS coated sample and BNNT coated sample cooled 83% and 75% faster than the non-coated Si sample, respectively. All samples were coated on the same silicon wafer substrate, which had been cut into separate pieces to provide the different samples with the same dimensions, and tested in the same way. Each sample was first heated, and then allowed to cool by turning off the heater. The tip of a thermocouple (TC) was in contact with the back surface of the samples at the tip of the suspended end, as shown schematically in FIG. 5A.

The BNNT and BNNS data suggests that samples made with both BNNT and BNNS materials (e.g. with BNNTs grown on top of BNNSs) may exhibit similar, or possibly improved, cooling curves and gradients as compared to the single-material samples described above. Substrates with both BNNSs and BNNTs may be produced using a multi-step process. For example, BNNSs may be synthesized on the surface of a substrate to provide a large surface contact area between the BNNSs and the substrate. Then, a MgO, Fe, or Ni, etc. catalyst film may be deposited on top of these BNNSs for subsequent growth of BNNTs on top of the BNNSs, as described by Lee et al (Chem. Mater. 22, 1782 (2010), which is incorporated by reference herein in its entirety). An exemplary catalyst film would be 10 nm thick, although other film thicknesses greater or less than this are also possible. The BNNSs provide good surface contact whereas the BNNTs provide a large surface area (larger than that of the BNNSs) to dissipate heat to the surrounding cool air/media. Such multi-layered materials may be useful for heat management applications as well.

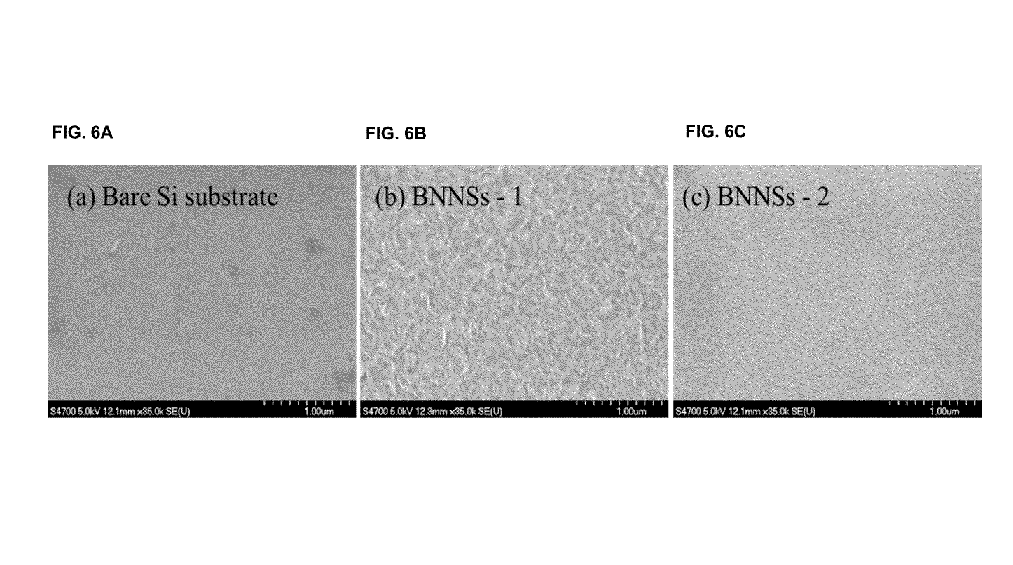

The effect of BNNS feature size on the cooling rate was also analyzed. Three samples were tested, with the first one being a bare silicon substrate. The second sample was a silicon substrate coated with BNNSs having “large” features (BNNS-1). As shown in FIG. 6B, the large feature sizes are in a range of about 250 to about 400 nm and are formed at a location closer to the precursor materials, much like locations 1, 2, 3, and 4 in FIG. 3, and FIG. 4A-FIG. 4F. The third sample is a silicon substrate coated with BNNSs that have “fine” features (BNNS-2). As shown in FIG. 6C, the fine feature size is about 100 nm. Under conditions used herein, BNNSs having these fine features are formed at locations further away from the precursor materials, such as locations 5 and 6 in FIG. 3. As shown in FIG. 6A-FIG. 6C, the surface morphology of the bare silicon substrate is smooth (FIG. 6A, while the wavy 3D BNNSs can be clearly seen in BNNSs-1 (FIG. 6B). The wavy BNNSs on BNNSs-2 (FIG. 6C) have smaller feature sizes than those in BNNSs-1.

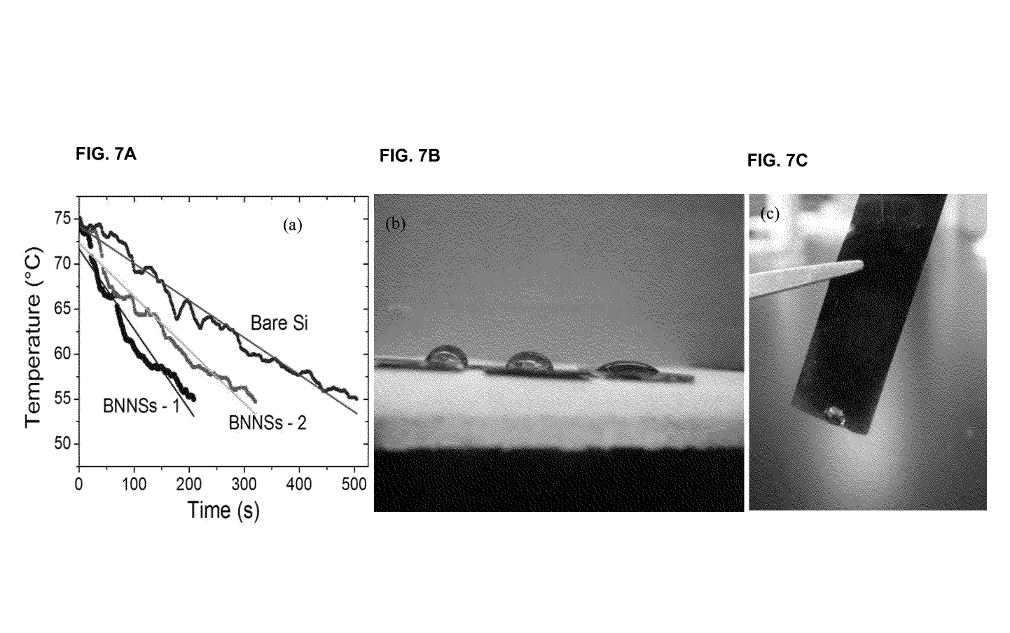

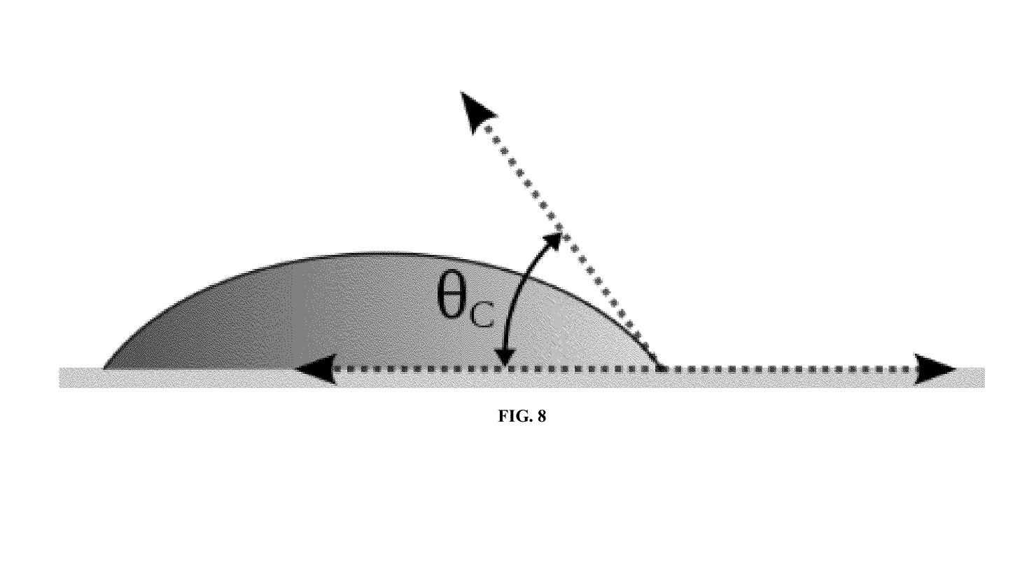

All samples were first brought to an equilibrium temperature of 75° C. The heater was then turned off, and the temperature of the sample was recorded as a function of time, as shown in FIG. 7A. All samples were still in contact with the hot heater, which was cooling from 445° C. to 200° C. during the measurement period. The time required for each sample to cool from about 75° C. to about 55° C. is about 205 s, about 310 s, and about 505 s, for BNNSs-1, BNNSs-2, and Si, respectively. These data provide estimated cooling rates for BNNSs-1, BNNSs-2, and bare Si of about 0.0976±0.0018° C./s, about 0.0645±0.0005° C./s, and about 0.0396±0.0003° C./s, respectively. Therefore, substrates coated with BNNSs-1 and BNNSs-2 cooled faster than the bare Si by 2.46 times and 1.63 times, respectively. Without being bound by theory, the larger wavy features of BNNSs-1 may be responsible for the faster cooling rate by convection and radiation to the surrounding air, when compared to BNNSs-2.

Surprisingly, the wavy BNNSs disclosed herein are not superhydrophobic, apparently different from BNNSs with straight and opened edges reported by Yu et al, 2010 and Pakdel et al, 2011. FIG. 7B shows the side view of samples including BNNSs-2, BNNSs-1, and bare Si (left to right) with water droplets on top of each. As shown, the water contact angle, θ_{c} is less than 90°. A superhydrophobic surface has a contact angle of at least 150°, when measured as shown in FIG. 8. A water droplet will not wet a superhydrophobic surface and instead will roll around on top of the sample surface. As shown in FIG. 7C, a water droplet sticks to the wavy BNNSs-2 sample and does not roll off, indicating that the inventive BNNSs are not superhydrophobic. Accordingly, wavy BNNSs can be wetted with water, like silicon, thus enabling applications with water-based coolants.

Peeling and Transfer of Wavy BNNSs to Secondary Surfaces.

Wavy BNNSs may be peeled from their original substrate and transferred to a second substrate, which facilitates use of BNNSs for applications such as surface cooling on surfaces other than the substrate on which the BNNSs are grown. For example, wavy BNNS samples were first grown on an oxidized silicon substrate (500 nm thick silicon oxide). These samples were then coated with a polymer layer of about 1 mm poly(methyl methacrylate) (PMMA) by spin coating at a spin rate of about 1000 rpm. In an embodiment, the thickness of the polymer is at least about 0.5 mm. Any suitable polymer may be used, including, for example, PMMA, polydimethylsiloxane (PDMS), poly(ethylene oxide) or PEO, and poly(ethylene terephthalate) or PET. The PMMA coating was then cured for about 30 minutes on a warm hot plate (about 100° C.). In some embodiments, the curing may occur at a temperature between about 70° C. to about 100° C., and the time of curing may range from between about 15 to about 30 minutes. Generally, the time and temperature of the curing is related to the melting or softening point of the polymers, and suitable times and temperatures are employed which are adequate to evaporate the solvent inside the polymer film to make it solidify.

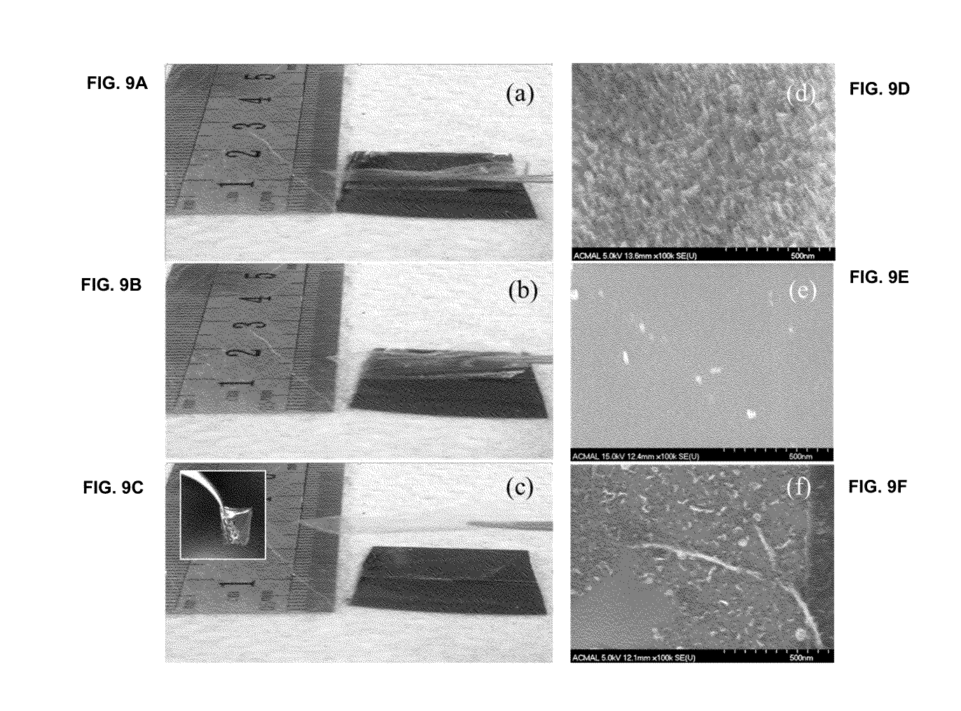

Subsequently, the oxidized silicon layer on the silicon substrate was etched by aqueous HF acid at a concentration of about 50% for about 2 minutes. In general, the etching conditions are related to the type of substrate used. For example, sapphire can be etched by a mixture of H₂SO₄ and H₃PO₄ and HF can also be used for etching a quartz substrate. This etching promotes the peeling of the PMMA/BNNS film as shown in FIG. 9A-FIG. 9C. As shown in the insert of FIG. 9C, a free standing PMMA/BNNS film can be picked up using tweezers. The as-grown wavy BNNSs (FIG. 9D) are no longer found on the substrate after the peeling process (FIG. 9E), indicating that a complete transfer has occurred. All the wavy BNNSs were transferred to the PMMA coating with very few residual wavy BNNSs remaining on the substrate. The BNNSs attached to the PMMA coating can then be placed on a second substrate or surface (as tested on Si and oxidized Si substrates) by placing the PMMA/BNNS films on the target secondary surface followed by removal of the PMMA. The PMMA coating can be removed either by combustion in air (300-500° C.), washing with acetone at room temperature, or soaking with toluene, acetone, or other organic solvents. The transferred BNNSs on a secondary Si substrate are shown in FIG. 9F. In this manner, the removal of the polymer from the polymer-coated boron nitride nanosheet occurs such that the boron nitride nanosheets are retained on an item. In certain embodiments, it may be desirable to not remove the polymer coating.

Accordingly, a series of wavy BNNS samples with scrolled edges can be synthesized on a substrate in one setting using a CVD approach. The formation of wavy BNNSs is related to the growth pressure and the ammonia gas flow rate, and the location of the precursor powders. Wavy BNNSs are effective surface coatings which may promote heat dissipation from hot surfaces to their surroundings (air and liquids). This heat management application can be used with the disclosed wavy BNNSs. These wavy BNNSs have close-ended and scrolled edges, which may contribute to their hydrophilicity, making them useful for applications to systems with water-based coolants.

The wavy BNNSs can be peeled off from a substrate by selective etching of the BNNS-substrate interface. For example, a silicon oxide layer between the BNNSs and a silicon substrate can be etched effectively by HF. This can lead to free standing wavy BNNSs, free standing PMMA/BNNS, or free standing polymer/BNNS films, resulting from the samples being etched without polymer coating, etched after coating with PMMA polymer, or etched after coating with other polymer films. The coating of a polymer film on top of the wavy BNNSs before etching may, in certain embodiments, simplify the handling process.

The wavy BNNSs may be transferred to a secondary surface or substrate by applying the BNNS/polymer films to the secondary substrate, optionally followed by the removal of the polymer coating. The removal of the polymer coating can be performed by washing with organic solvents or combustion at, for example, temperatures between about 100 and about 800° C.

The transferred wavy BNNSs can be applied to plastic surfaces and be used to promote the cooling of, for example, plastic packaging materials (or encapsulates) found on electronic devices, high-power electronic devices, high-power light emitting diodes (LEDs), lithium ion batteries, and other energy storage devices. The wavy BNNSs may also be used with electric switches to promote the cooling of any wires carrying a high current, such as for switches used to carry the current from the battery to the engine in electric vehicles. Plastic or polymer surfaces coated with BNNSs can be used as low-cost, lightweight, alternative heat sink structures in various electronic or electrical devices, including computers and smart phones, vehicles, engines, and power plants. The transferred BNNSs can also be applied to the surfaces of metallic heat sinks or other non-plastic or non-polymeric surfaces, as well.

BNNSs with BNNTs

As discussed above, BNNSs may be synthesized on the surface of a substrate, and then a catalyst film may be deposited on top of these BNNSs for subsequent growth of BNNTs on top of the BNNSs, as described by Lee et al (Chem. Mater. 22, 1782 (2010), which is incorporated by reference herein in its entirety). More specifically, these BNNTs-BNNSs include a surface and a coating at least partially coating the surface, where the coating comprises a first layer in direct contact with the surface that includes a plurality of BNNSs, and a second layer in contact with the first layer that includes a plurality of BNNTs.

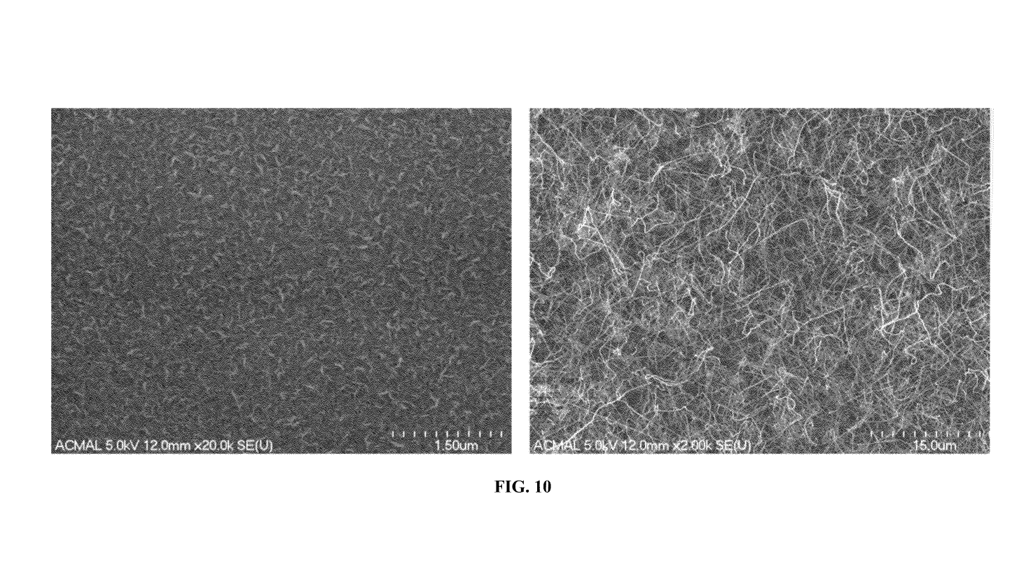

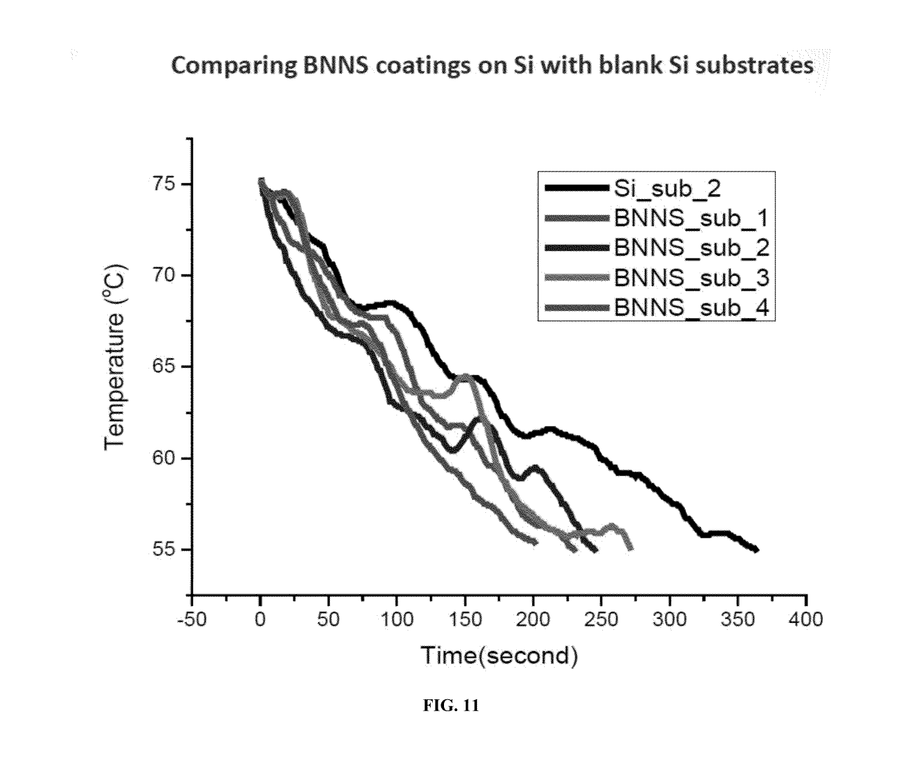

FIG. 10 is a pair of SEM images showing the morphology of compositions comprising BNNSs applied to a Si substrate before being overgrown with BNNTs on top of the BNNSs (left) and after being overgrown with BNNTs on top of BNNSs (right).

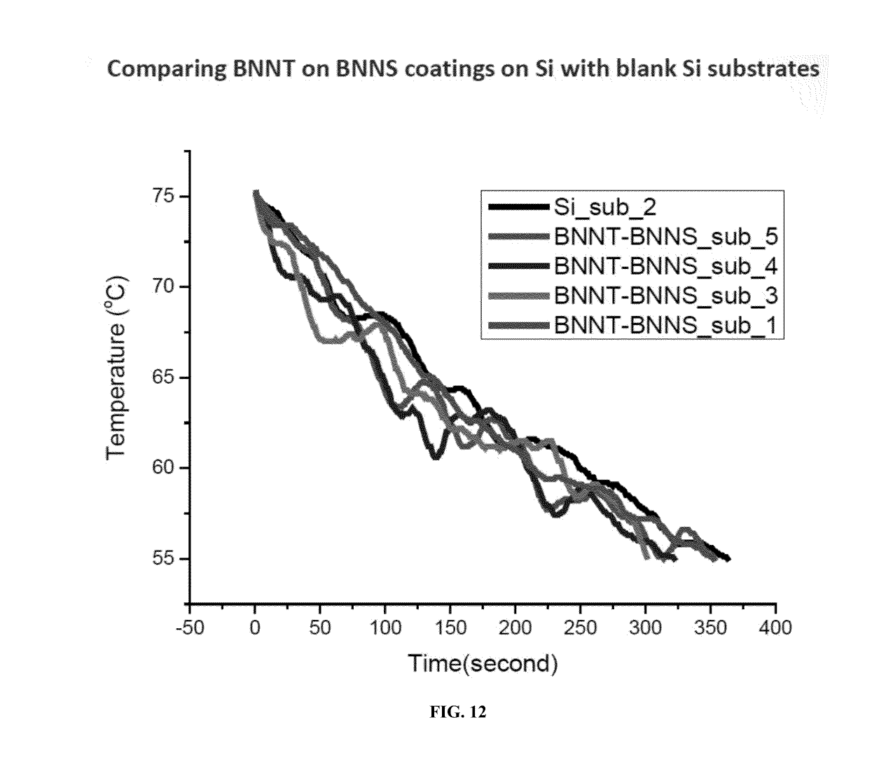

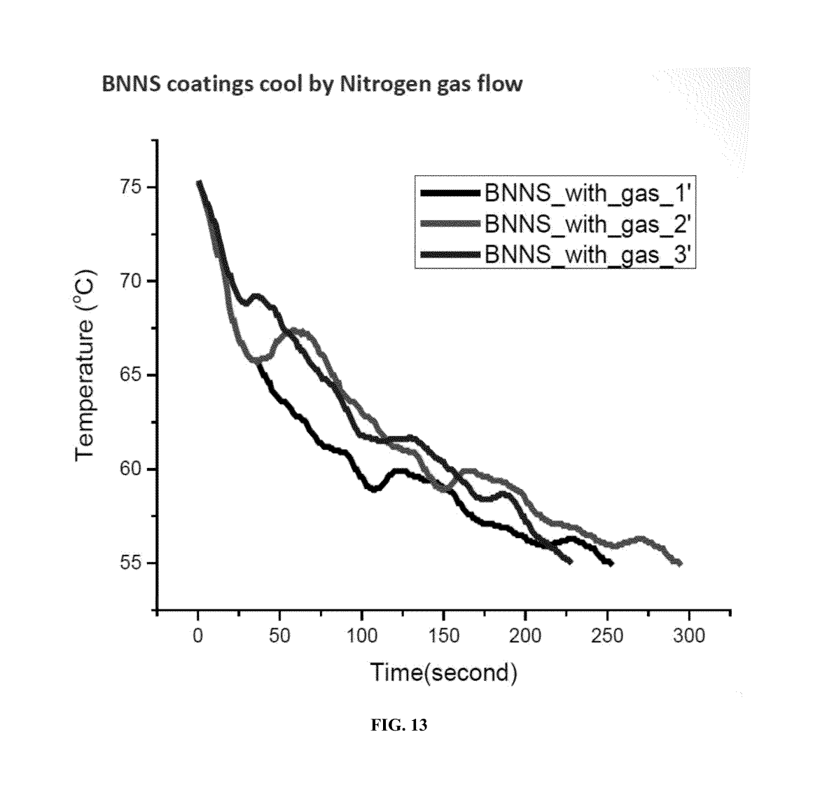

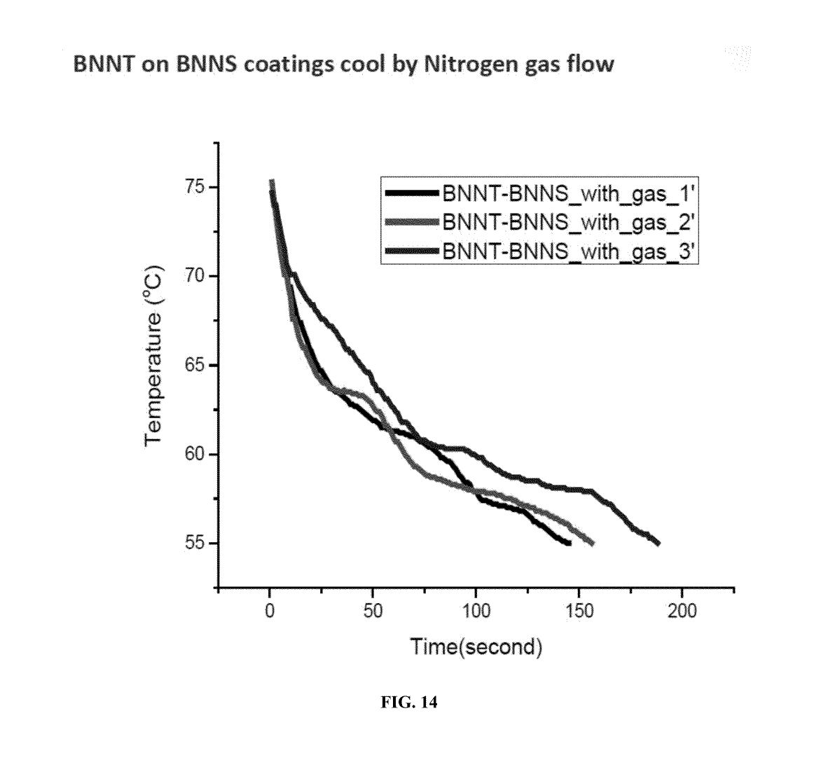

Heat dissipation properties of these BNNTs-BNNSs applied to a Si substrate were compared to the heat dissipation properties of BNNSs applied to a Si substrate and to a Si substrate alone. Specifically, cooling curves under ambient conditions (room temperature and pressure) were obtained for BNNSs applied to Si substrates as compared to a Si substrate alone (FIG. 11) and for BBNTs-BNNSs on Si substrates as compared to Si substrate alone (FIG. 12). Cooling curves were also obtained under conditions where Nitrogen gas was flowed onto samples including BNNSs applied to Si substrates (FIG. 13), BNNTs-BNNSs on Si substrates (FIG. 14) and Si substrates alone (not graphically shown). For the Nitrogen cooled samples, the Nitrogen gas was flowed downward at a rate of 1 SCFH onto the center of the samples through a 0.25 inch gas pipe located 5 mm above the samples.

The average cooling rates from 75° C. to 60° C. were calculated and are shown in the Table below:

| | Average cooling rate (in | Average cooling rate (in |
|---|---|---|
| | ° C./s) from 75° C. | ° C./s) from 75° C. to |
| | to 60° C. under | 60° C. in the presence of a |
| Structure | ambient conditions | nitrogen gas flow. |
| Blank Si | 0.054 ± 0.005° C./s | 0.125 ± 0.025° C./s |
| Substrate | | |
| BNNSs coating | 0.090 ± 0.010° C./s | 0.150 ± 0.020° C./s |
| on Si Substrate | | |
| BNNTs-BNNSs | 0.060 ± 0.006° C./s | 0.280 ± 0.020° C./s |
| coating on Si | | |

As shown, under ambient conditions, the sample with the BNNSs alone cooled more efficiently between 75-60° C. However, under a Nitrogen gas flow, the samples with BNNTs-BNNSs cooled substantially more efficiently from 75-60° C. than both the BNNSs or the Si substrate alone.

Each of the following citations is fully incorporated herein by reference in its entirety.
1. Lee et al, “Introduction to B-C-N materials,” in Chapter 1 of B-C-N Nanotubes and Related Nanostructures, Lecture Notes in Nanoscale Science and Technology (Springer), Vol. 6, Yoke Khin Yap (Ed.) (2009) pp 1-22.
2. Yap, “B-C-N Nanotubes, Nanosheets, Nanoribbons, and Related Nanostructures,” in the AZoNano.com “Nanotechnology Thought Leaders” Series (Apr. 20, 2011). Available online at http://www.azonano.com/article.aspx?ArticleID=2847.
3. Lee et al., Chem. Mater. 22, 1782 (2010).
4. Lee et al., Nanotechnology 19, 455605 (2008).
5. Yu et. al., ACS Nano 4, 414 (2010).
6. Pakdel et al., ACS Nano 5, 6507 (2011).

Various features and advantages of the invention are set forth in the following claims.

What is claimed is:

1. A method of making a boron nitride nanosheet, comprising:
heating solid boron, magnesium oxide and iron oxide compounds in a furnace in the presence of ammonia gas and a substrate, such that the boron nitride nanosheet is deposited on the substrate,
wherein the boron nitride nanosheet comprises a first end, a second end, and a sheet between the first and second ends, wherein the first end is engaged with the substrate and the sheet extends upward away from the substrate and then curls back towards the substrate so that the second end is oriented towards the substrate.

2. The method of claim 1, wherein the molar ratio of boron:magnesium oxide:iron oxide is 4:1:1.

3. The method of claim 1, wherein the flow rate of the ammonia gas is at least about 250 sccm.

4. The method of claim 1, wherein the pressure of the ammonia gas is at least about 3 torr.

5. The method of claim 1, wherein the heating step is performed for between about 30 minutes and about 2 hours at a temperature between about 1100° C. and about 1300° C.

6. The method of claim 1, wherein the substrate comprises silicon.

7. A boron nitride nanosheet formed by the method of claim 1.

8. A composition comprising a substrate having a surface at least partially coated with a coating comprising a plurality of boron nitride nanosheets made by the method of claim 1.

9. A method of applying a boron nitride nanosheet to a surface, comprising:
applying a polymer to the boron nitride nanosheet formed by the method of claim 1 to form a polymer-coated boron nitride nanosheet;
removing the polymer-coated boron nitride nanosheet from the substrate; and
applying the polymer-coated boron nitride nanosheet to the surface.

10. The method of claim 9, further comprising removing the polymer coating from the boron nitride nanosheet.

11. The method of claim 10, wherein removing the polymer coating from the boron nitride nanosheet comprises at least one of treatment of the coating with a solvent or combustion of the coating.

12. The method of claim 9, wherein the polymer comprises poly(methylmethacrylate).

13. The method of claim 9, wherein the step of applying a polymer to the boron nitride nanosheet to form a polymer-coated boron nitride nanosheet comprises curing the polymer for at least about 30 minutes at a temperature of at least about 80° C.

14. The method of claim 9, wherein the polymer is applied at a thickness of at least about 1 mm.

15. The method of claim 9, wherein removing the polymer-coated boron nitride nanosheet from the substrate comprises treatment of the polymer-coated boron nitride nanosheet with hydrofluoric acid.

16. A method of dissipating heat from a surface, comprising applying a boron nitride nanosheet to the surface according to the method of claim 9.

17. An item comprising a surface at least partially coated with a coating comprising a plurality of boron nitride nanosheets formed by the method of claim 1.

18. A composition comprising a substrate and a boron nitride nanosheet comprising a first end, a second end, and a sheet between the first and second ends, wherein the first end is engaged with the substrate and the sheet extends upward away from the substrate and then curls back towards the substrate so that the second end is oriented towards the substrate.

19. A composition comprising:
a surface and a coating at least partially coating the surface;
wherein the coating comprises a first layer in direct contact with the surface that includes a plurality of boron nitride nanosheets, and a second layer in contact with the first layer that includes a plurality of boron nitride nanotubes

20. The composition of claim 19, wherein the first layer comprises a plurality of boron nitride nanosheets comprising a first end, a second end, and a sheet between the first and second ends, wherein the first end is engaged with the surface and the sheet extends upward away from the surface and then curls back towards the substrate so that the second end is oriented towards the surface.
